(19) United States
(12) Patent Application Publication
(10) Pub. No.: US 2006/0164813 A1
(43) Pub. Date: Jul. 27, 2006

(54) Semiconductor package and semiconductor module

(75) Inventors: Shimpei Yoshioka, Yokohama-shi (JP); Yukihiro Ikeya, Yokohama-shi (JP); Naotake Watanabe, Yokohama-shi (JP); Nobumitsu Tada, Hachioji-shi (JP); Masakazu Shindome, Fuchu-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/289,487

(22) Filed: Nov. 30, 2005

(30) Foreign Application Priority Data
Nov. 30, 2004 (JP) 2004-346527
Jul. 27, 2005 (JP) 2005-217178

(51) Int. Cl. H05K 7/20

(52) U.S. Cl. 361/717; 361/688; 361/711

(57) ABSTRACT

A semiconductor package includes a plate-like semiconductor element having a first power terminal and a control terminal on a main surface, and a second power terminal on a rear surface; a first power electrode plate positioned to face with the main surface of the semiconductor element, and including a first power electrode joined to the first power terminal by soldering; a second power electrode plate positioned to face with the rear surface of the semiconductor element, and including a second power electrode joined to the second power terminal by soldering; and an insulating substrate positioned between the semiconductor element and the first electrode plate, and including a control electrode joined to the control terminal by soldering.

### CROSS REFERENCE TO THE RELATED APPLICATIONS

This application is based upon and claims the benefit of priority from the prior Japanese Patent Applications No. 2004-346,527 filed on Nov. 30, 2004 and No. 2005-217,178 filed on Jul. 27, 2005, the entire contents of which are incorporated herein by reference.

### BACKGROUND OF THE INVENTION

1. Field of the Invention

The present invention relates to a semiconductor package and a semiconductor module, and more particularly relates to a semiconductor package which includes power semiconductor elements and constitutes a power control unit such as an inverter and a converter, and a semiconductor module constituted by a plurality of semiconductor packages.

2. Description of the Related Art

Generally, IGBT elements (switching elements), IEGTs, MOS-FETs and so on are used as power semiconductor elements. They are provided with front power terminals and control terminals on their front surfaces, and rear power terminals on their rear surfaces. When used as a power semiconductor element, an IGBT element has an emitter electrode as the front power terminal, a collector electrode as the rear power terminal, and a gate electrode as the control terminal.

When power semiconductor elements are mounted on a substrate and are assembled as a semiconductor package, rear power terminals of the semiconductor elements are soldered and connected to electrodes of a package. Further, front power terminals and control terminals of the semiconductor elements are bonded to electrodes of the package using aluminum wires and wire-bonding process (as described in Japanese Patent Laid-Open Publications No. 2003-110,064 and No. 2002-164,485, for example).

However, the wire bonding suffers from the following technical problems. The aluminum wires are bonded on one-by-one basis, which takes time to bond the terminals. Further, the wires loop and are lengthened, which raises wiring inductance. Still further, the wires are adversely affected by vibrations, are easily broken, and tend to be short-circuited with adjacent wires.

In order to cope with the foregoing problem, there is a tendency that thin aluminum films are bonded onto front power terminals of semiconductor elements in place of wires, or plates and lead wires are soldered so that they are used as electrodes. Recently, it attracts attention to select solder-able materials as front power terminals of semiconductor terminals, and to solder plates or lead wires to the front power terminals. However, bonded wires are used as lead wires from control terminals.

Referring to FIG. 1 of the accompanying drawings, such a semiconductor package 1 includes a plate-like IGBT element 2 (semiconductor element), a first electrode plate 3 and a second electrode plate 4. The first and second electrode plates 3 and 4 sandwich the IGBT element 2 between them.

The IGBT element 2 has an emitter electrode 2a (power terminal), a gate electrode 2b (control terminal), and an emitter-sense electrode 2c (control terminal) on its front surface, and a collector electrode 2d (power terminal) on the rear surface. The emitter electrode 2a is soldered to the first electrode plate 3, while the collector electrode 2d is soldered to the second electrode plate 4.

An insulating substrate 5 is arranged adjacent to the IGBT element 2, has bonding pads (not shown) on its rear surface, and is soldered to the second electrode plate 4 using the bonding pads. A solder sheet cut to a predetermined size, a printed soldering paste, solder prepared by the plating process, or solder prepared by the vacuum evaporation process is used for the foregoing connection. The second electrode plate 4 is fixedly attached to a ceramics metal-plated substrate or a conductive member (not shown) such as a bus bar, and serves as a collector wiring and a radiator. An emitter wiring from the first electrode plate 3 is made of an aluminum ribbon 8.

The gate electrode 2b and the bonding pad 5b are electrically connected using an aluminum bonding wire 6b. The emitter-sense electrode 2c and the bonding pad 5a are electrically connected using an aluminum bonding wire 6a. Further, a control wiring 7a is soldered to the bonding pad 5a while a control wiring 7b is soldered to the bonding pad 5b.

With the foregoing semiconductor package 1, not only the gate electrode 2b and emitter-sense electrode 2c of the IGBT element 2 but also the bonding pads 5a and 5b on the insulating substrate 5 should be mounted on the same plane in order to accomplish the wire bonding. In addition, the following spaces have to be secured: a bonding space; a space for preventing short circuiting of the adjacent bonding wires 6a and 6b; and a space for preventing short-circuiting between the bonding wires 6a and 6b and the control wirings 7a and 7b. As a result, the second electrode plate 4 should be enlarged, which will inevitably make the semiconductor package 1 larger. Further, it is not preferable in view of the investment of plant and equipment and process control that the wire bonding process is left uncompleted in a manufacturing process of the semiconductor package 1.

### SUMMARY OF THE INVENTION

The invention has been contemplated to overcome the foregoing problems of the related art, and is intended to provide a compact semiconductor package in which semiconductor elements are connected without a wire bonding process, and a semiconductor module constituted by such semiconductor package.

According to a first aspect of the invention, there is provided a semiconductor package, which includes a plate-like semiconductor element having a first power terminal and a control terminal on a main surface, and a second power terminal on a rear surface; a first power electrode plate positioned to face with the main surface of the semiconductor element, and including a first power electrode joined to the first power terminal by soldering; a second power electrode plate positioned to face with the rear surface of the semiconductor element, and including a second power electrode joined to the second power terminal by soldering; and an insulating substrate positioned between the semiconductor element and the first electrode plate, and including a control electrode joined to the control terminal by soldering.

In accordance with a second aspect, there is provided a semiconductor module constituted by the foregoing semiconductor package, and the semiconductor package being sandwiched by first and second conductive members.

### BRIEF DESCRIPTION OF THE DRAWINGS

In all Figures identical parts have identical reference numbers.

FIG. 1 is a perspective view of a semiconductor package of the related art;

FIG. 2 is a perspective view of a semiconductor package according to a first embodiment of the invention;

FIG. 3 is an exploded perspective view of the semiconductor package of FIG. 2;

FIG. 4 is an exploded perspective view of an insulating substrate and an IGBT element of the semiconductor package of FIG. 2;

FIG. 5 is an exploded perspective view of an insulating substrate and a first electrode plate of the semiconductor package of FIG. 2;

FIG. 6 is a perspective view of the insulating substrate and the first electrode plate of the semiconductor package of FIG. 2;

FIG. 7 is a cross section of the semiconductor package, taken along line A-A in FIG. 2;

FIG. 8 is a cross section of a semiconductor package according to a second embodiment, taken in a plane corresponding to the plane taken along line A-A in FIG. 2;

FIG. 9 is a cross section showing how the semiconductor package of FIG. 8 is made in a first manufacturing step;

FIG. 10 is a cross section showing how the semiconductor package of FIG. 8 is made in a second manufacturing step;

FIG. 11 is a cross section of a semiconductor package according to a third embodiment, taken in a plane corresponding to the plane taken along line A-A in FIG. 2;

FIG. 12 is a cross section of a semiconductor package according to a fourth embodiment, taken a plane corresponding to the plane along line A-A in FIG. 2;

FIG. 13 is a cross section of a semiconductor package according to a fifth embodiment, taken a plane corresponding to the plane taken along line A-A in FIG. 2;

FIG. 14 is a cross section of a semiconductor package according to a sixth embodiment, taken a plane corresponding to the plane along line A-A in FIG. 2;

FIG. 15 is a side elevation of a semiconductor module according to a seventh embodiment;

FIG. 16 is a top plan view of the semiconductor module of FIG. 15;

FIG. 17 is a side elevation showing how a semiconductor module in an eighth embodiment is made in a first manufacturing step;

FIG. 18 is a side elevation showing how the semiconductor module in an eighth embodiment is made in a second manufacturing step; and

FIG. 19 is a side elevation of a semiconductor module according to a ninth embodiment.

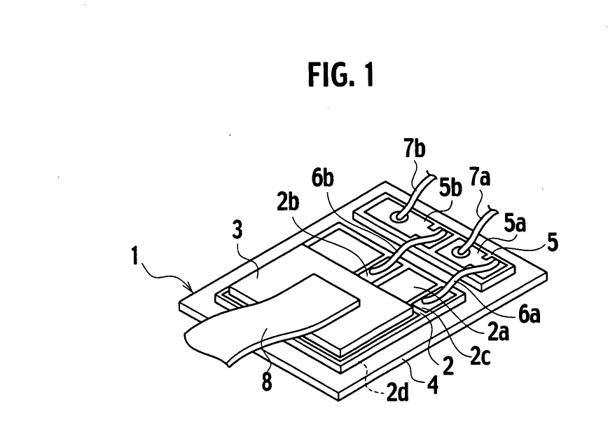

### DETAILED DESCRIPTION OF THE INVENTION

### First Embodiment

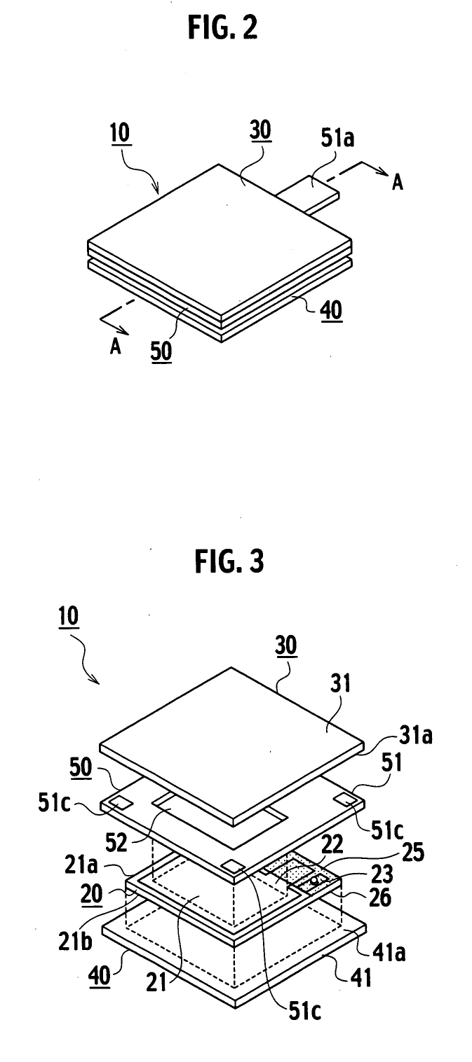

The invention will be described with respect to a first embodiment shown in FIG. 2 to FIG. 7.

Referring to FIG. 2 and FIG. 3, a semiconductor package 10 is constituted by an IGBT element 20 (a semiconductor element) as a power semiconductor element; a first electrode plate 30 on a main surface of the IGBT element 20; a second electrode plate 40 on a rear surface of the IGBT element 20; and an insulating substrate 50 interposed between the first electrode plate 30 and the IGBT element 20, all of which are stacked one over after another. The IGBT element 20 is smaller than the first electrode plate 30, second electrode plate 40 and insulating substrate 50. An peripheral edge of the IGBT element 20 is located inward of peripheral edges of the first electrode plate 30, second electrode plate 40 and insulating substrate 50.

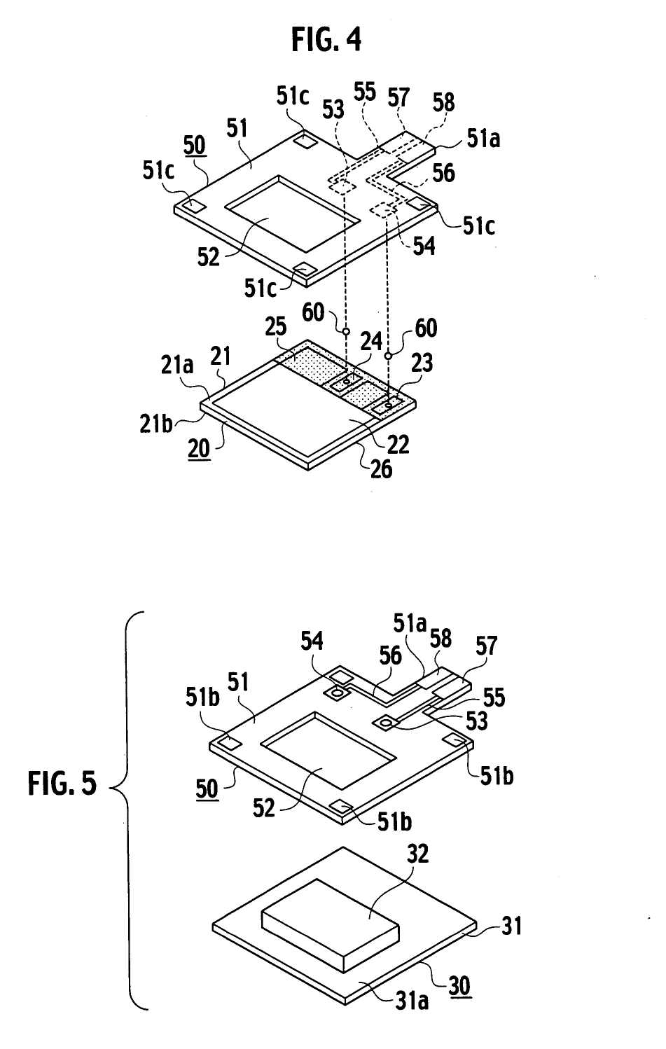

As shown in FIG. 3 and FIG. 4, the IGBT element 20 is an IGBT mounted on a small plate-like semiconductor chip 21. An emitter electrode 22 (a first power terminal), a gate electrode 23 (a control terminal), and an emitter-sense electrode 24 (a control terminal) are arranged on a front surface 21a of the semiconductor chip 21. A solder-resist film 25 is printed around the gate electrode 23 and the emitter-sense electrode 24 in order to prevent short-circuit due to solder splash. A collector electrode 26 (a second power terminal) is provided on a rear surface 21b of the semiconductor chip 21. The solder-resist film 25 has an opening whose shape depends upon solder quantity and type of solder (a shape of a solder ball, a solder sheet and so on, for example). If the solder ball is used, the opening is circular, for instance.

The first electrode plate 30 includes a plate-like substrate body 31 made of a conductive copper sheet or the like. Refer to FIG. 3 and FIG. 5. The conductive copper sheet is preferable in view of price, electrical conductivity, and thermal conductance. Alternatively, different materials may be used (as described later). A protrusion 32 projects on a surface 31a of the substrate body 31, serves as a first power electrode, and is in contact with the emitter electrode 22 of the IGBT element 20 (the protrusion 32 being called the “first power electrode 32”). The first electrode plate 30 is electrically connected to the emitter electrode 22. The surface 31a faces with the IGBT element 20. Refer to FIG. 5.

The second electrode plate 40 includes a plate-like substrate body 41 which is made of a conductive copper sheet or the like. Refer to FIG. 3. A surface 41a of the substrate body 41 faces with the IGBT element 20, serves as a second power electrode, and is in contact with the collector electrode 26 of the IGBT element 20 (the surface 41a being called the “second power electrode 41a”). The second electrode plate 40 is electrically connected to the collector electrode 26. The substrate body 41 may be made of the same material as that of the substrate body 31 or may be made of another material.

The insulating substrate 50 includes a plate-like substrate body 51 made of a glass epoxy resin, polyimide resin or the like as shown in FIG. 3 to FIG. 5. The substrate body 51 has a through-hole 52 (opening) which as a contour similar to the first power electrode 32. The first power electrode 32 is fitted into the through-hole 52 and passes through the through-hole 52. Further, the substrate body 51 has a ledge 51a, which extends outward from peripheral edges of the first and second electrode plates 30 and 40 as shown in FIG. 4 and FIG. 5. A bonding pad 51b is provided on a surface of the substrate body 51 as shown in FIG. 5, the surface facing with the second electrode plate 40. Further, a bonding pad 51c is on the other surface of the substrate body 51 (shown in FIG. 3 and FIG. 4) in order to support the first electrode plate 30, the surface facing with the first electrode plate 30. The bonding pad 51c extends outward from the peripheral edge of the IGBT element 20.

Referring to FIG. 4 and FIG. 5, bonding pads 53 and 54 (control electrodes) are provided on the substrate body 51, and face with the gate electrode 23 and emitter-sense electrode 24 of the IGBT element 20. Further, the substrate body 51 includes wirings 55 and 56 which are connected to the bonding pads 53 and 54. Still further, external connection terminals 57 and 58 are positioned on the ledge 51a, and are connected to the wirings 55 and 56.

A solder-resist film (not shown) extends over areas except where the bonding pads 53 and 54 and the external connection terminals 57 and 58. The solder-resist film may be made of any material. A shape of the solder-resist film depends upon a shape of a solder ball, a solder sheet and so on. If the solder ball is used, a through-bore on the solder-resist film is circular, for instance.

The IGBT element 20, first electrode plate 30, second electrode plate 40 and insulating substrate 50 are electrically connected and joined as described hereinafter.

As shown in FIG. 4, FIG. 5 and FIG. 7, the emitter electrode 22 of the IGBT element 20 and the first power electrode 32 are soldered and electrically connected via a solder layer 70. The solder layer 70 is formed between the IGBT element 20 and the first power electrode 32.

The gate electrode 23 of the IGBT element 20 and the bonding pad 54 on the insulating substrate 50 are soldered using a solder ball 60, so that they are electrically connected via a solder layer formed between the IGBT element 20 and the insulating substrate 50. Refer to FIG. 4. Further, the emitter-sense electrode 24 of the IGBT element 20 and the bonding pad 53 on the insulating substrate 50 are soldered using another solder ball 60, so that they are electrically connected via a solder layer 71 formed between the IGBT element 20 and the insulating substrate 50. Refer to FIG. 4 and FIG. 7.

Referring to FIG. 3 and FIG. 7, the collector electrode 26 of the IGBT element 20 is soldered and electrically connected to the second power electrode 41a of the second electrode plate 40 via a solder layer 72. The solder layer 72 is formed between the IGBT element 20 and the second electrode plate 40.

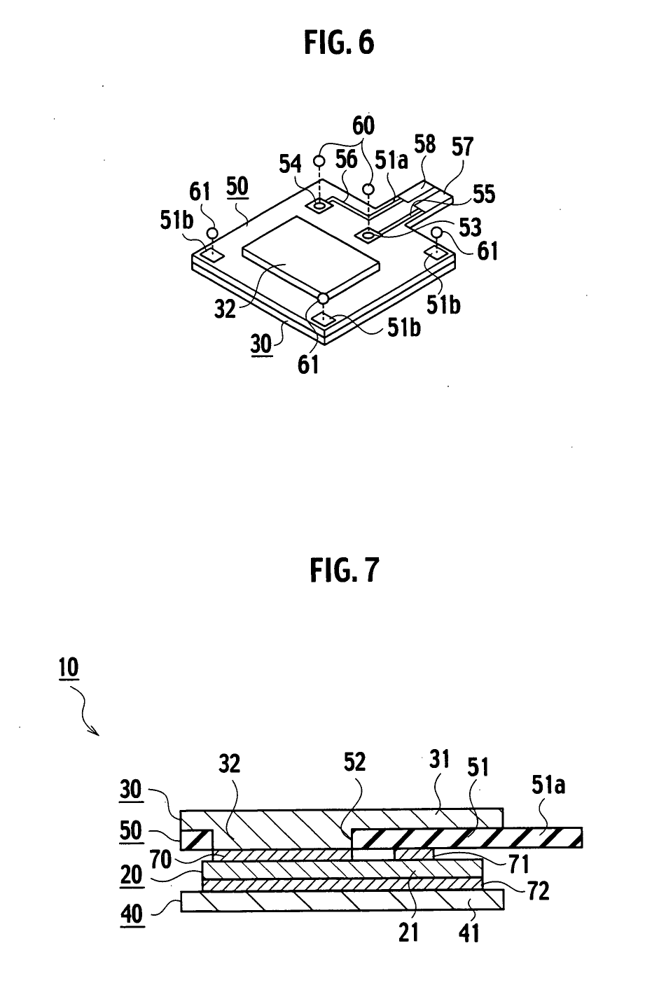

As shown in FIG. 3 and FIG. 6, the second electrode plate 40 and the bonding pad 51b of the insulating substrate 50 are connected by melting a solder ball cover 61 (a spacer) on the bonding pad 51b. The solder ball cover 61 keeps the second electrode plate 40 and the insulating substrate 50 spaced apart, and is made by coating a solder flux on a metallic core or a non-metallic core such as plastics which is covered by a metal.

As shown in FIG. 3, the first electrode plate 30 and the bonding pad 51c of the insulating substrate 50 are connected by soldering, so that the first electrode plate 30 is fixed on the insulating substrate 50. The first and second electrode plates 30 and 40 are electrically insulated by the insulating substrate 50. The bonding pad 51c is made of a material having good solder wetting property. The bonding pad 51c is made of the same material as that of the bonding pad 51b, and is produced together with the bonding pad 51c, thereby reducing an increase of the manufacturing steps.

In the semiconductor package 10 of the first embodiment, the gate electrode 23 and emitter-sense electrode 24 of the IGBT element 20 face with the bonding pads 53 and 54 of the insulating substrate 50, so that they can be connected by the soldering. This means no wire bonding, no wire bonding space, and no space for preventing short-circuit caused by the wire bonding. This is effective in downsizing the semiconductor package 10. Further, absence of wire bonding process will lead to the reduction of facility investment and a production space.

Further, the insulating substrate 50 has the ledge 51a sticking out of the peripheries of the IGBT element 20 and the first and second electrode plates 30 and 40. The external connection terminals 57 and 58 connected to the bonding pads 53 and 54 are positioned on the ledge 51a. Therefore, the control wirings can extend out of the semiconductor package 10 without the wire bonding process.

The first electrode plate 30 includes the first power electrode 32 (protrusion) projecting toward the IGBT element 20. The insulating substrate 50 has the through-hole 52 (opening) through which the first power electrode 32 passes, so that the first electrode plate 30 is easily connected to the emitter electrode 22 of the IGBT element 20.

The insulating substrate 50 has the fixing pad 51c which faces with the first electrode plate 30. The insulating substrate 50 and the first electrode plate 30 can be reliably and firmly connected by soldering the fixing pad 51c on the insulating substrate 50.

The peripheral edges of the second electrode plate 40 and the insulating substrate 50 stick out of the peripheral edge of the IGBT element 20. Solder balls 61 are arranged between the second electrode plate 40 and the insulating substrate 50. The solder-coated balls 61 serve as spacers for the second electrode plate 40 and the insulating substrate 50 to be separate from each other, which is effective in protecting the IGBT element 20 against external shocks, and in improving the reliability of the components of the semiconductor package 10.

The solder-coated balls 61 include a metallic material on their surfaces, and are soldered to the second electrode plate 40 or the insulating substrate 50 using a soldering device. No additional device is required to solder the second electrode plate 40 or the insulating substrate 50, which will lead the reduction of the facility investment and a manufacturing space.

If it is very difficult to produce the solder-plated balls 61 as the spacers, ceramics-molded or resin-molded passive elements on the markets are usable. For instance, chip components of an electric resistor, a capacitor or an inductor can be used as spacers. The chip components have a standard size, so that chip components having the same height are easily obtained. They can be adhered to the second electrode plate 40 and the insulating substrate 50 with high parallelism. The chip components with passive elements include soldered electrodes at their opposite ends. Therefore, the chip components can be soldered to the substrate using the soldered electrodes, so that they can be easily assembled. In this case, the foregoing chip components do not have to function as a part of electric circuits of the semiconductor package 10 of this embodiment.

The present invention is not always limited to the foregoing embodiment, in which the first and second electrode plates 30 and 40 are made of copper materials. Alternatively, they may be made of conductive materials such as aluminum, molybdenum, copper-molybdenum alloy, copper-tungsten alloy, and so on in view of moldability, specific gravity, thermal expansion and so on. Further, the first and second electrode plates 30 and 40 may be cladding materials made of various substances. Still further, they may have their surfaces coated with different materials in order to enhance solder wetting property.

The first power electrode 32 of the first electrode plate 30 is made by a press-coining process. Alternatively, it may be made by a sintering process if it is made of a sintered material.

The soldering materials may be made of any material such as an ordinary Sn—Pb eutectic solder, lead-free solder, and Pb-rich high temperature solder. The solders applied between the collector electrode 26 and the second electrode plate 40 and between the emitter electrode 22 and the first electrode plate 30 are preferably solder sheets cut to a predetermined size, printed solder pastes, solders made by the plating or vacuum evaporation process, and so on. Further, the solders applied between the gate electrode 23 and the bonding pad 54 and between the emitter-sense electrode 24 and the bonding pad 53 are preferably solder balls, printed solder pastes, solder paste applied using a dispenser, and so on. The solder balls are easy to use and most preferable.

The insulating substrate 50 is in the shape of a double-faced sheet when it is soldered to the first electrode plate 30. Alternatively, the insulating substrate 50 is in the shape of a single-faced sheet when it is joined to the first electrode plate 30 with an adhesive or may be mechanically fixed to the first electrode plate 30. The insulating substrate 50 may be a flexible or bendable substrate or the like. When the insulating substrate 50 is especially resistant to heat, a BT resin imide substance is preferable.

Further, the insulating substrate 50 has the through-hole 52 through which the first power electrode 32 passes. Alternatively, a cut may be made in the insulating substrate 50 for this purpose.

### Second Embodiment

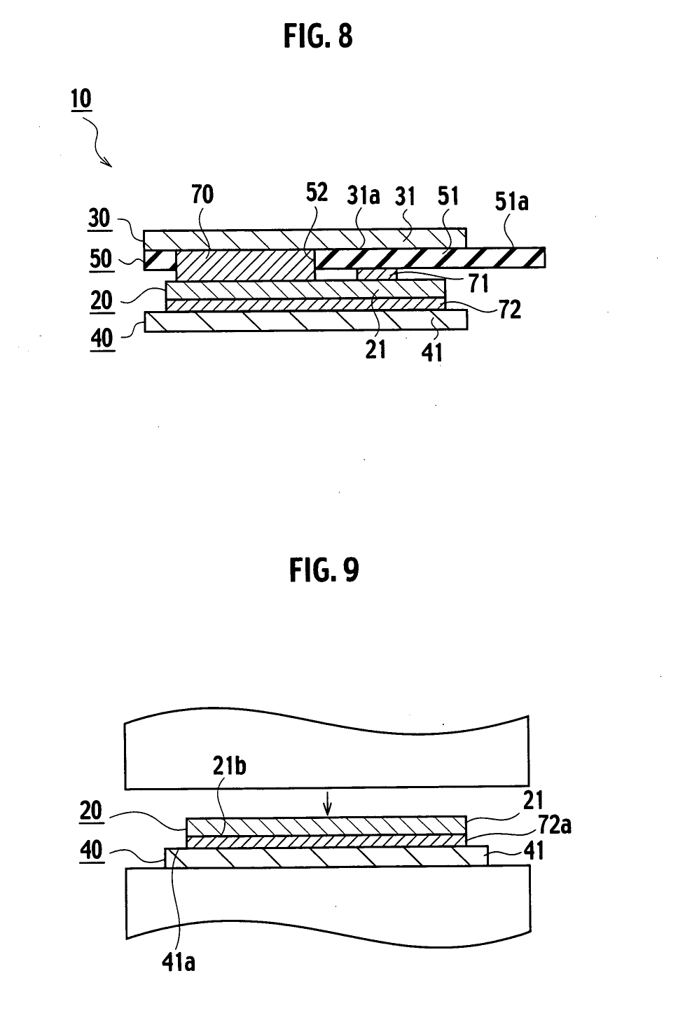

A semiconductor package 10 of a second embodiment will be described with reference to FIG. 8 to FIG. 10. The second embodiment is essentially identical to the first embodiment, but is different in the following respects.

Referring to FIG. 8, A first power electrode 31a of a first electrode plate 30 is flat, and faces with an IGBT element 20. The IGBT element 20 is soldered to the first and second electrode plates 30 and 40, and is soldered to the insulating substrate 50 by the diffused junction.

In the diffused junction process, materials are heated to a temperature equal to or less than their fusing points and are stuck fast to one another under a pressure, so that they are joined through mutual diffusion of their atoms while they are in a solid phase. Since the first power electrode 31a is flat, the first electrode plate 30 does not have a protrusion 32 in the shape of a projection shown in FIG. 5.

The first power electrode 31a on the first electrode plate 30 and an emitter electrode 22 on the IGBT element 20 are soldered and joined by the foregoing diffused junction (refer to FIG. 3). A solder layer 70 is formed between the IGBT element 20 and the first electrode plate 30 as shown in FIG. 8. The emitter electrode 22 and the first electrode plate 30 are electrically connected via the solder layer 70.

A gate electrode 23 on the IGBT element 20 is soldered and joined to a bonding pad 54 on the insulating substrate 50 by the diffused junction (refer to FIG. 4), so that a solder layer is formed between the IGBT element 20 and the insulating substrate 50. The gate electrode 23 and the bonding pad 54 are electrically connected via the solder layer. An emitter-sense electrode 24 on the IGBT element 20 and a bonding pad 53 on the insulating substrate 50 are soldered and joined by the diffused junction (refer to FIG. 4). A solder layer 71 is formed between the IGBT element 20 and the insulating substrate 50 as shown in FIG. 8. The emitter-sense electrode 24 and the bonding pad 53 are electrically connected via the solder layer 71.

A collector electrode 26 of the IGBT element 20 is soldered and joined to a second power electrode 41a of the second electrode plate 40 by the diffused junction (refer to FIG. 3). A solder layer 72 is formed between the IGBT element 20 and the second electrode plate 40 as shown in FIG. 8. The collector electrode 26 and the second electrode plate 40 are electrically connected via the solder layer 72.

The semiconductor package 10 is assembled in the following manner. Referring to FIG. 9, a solder sheet 72a is placed on the second electrode plate 40. The IGBT element 20 is put on the solder sheet 72a. The solder sheet 72a is made of an Sn group solder material. The second power electrode 41a of the second electrode plate 40 and the collector electrode 26 (shown in FIG. 3) on a rear surface 21b of the IGBT element 20 are plated by Ni/Au in order to enhance solder wetting property. Thereafter, the second electrode plate 40 and the IGBT element 20 are set in a reduced pressure pressing machine, and is pressed under various conditions (such as a pressing pressure of 4 MPa, a temperature of 210° C., and a reduced pressure of 10 Torr or less). The conditions depend upon compositions of the solder sheet 72a and so on. In the second embodiment, the pressing pressure is 0.5 Mpa to 10 MPa, the temperature is 150° C. to 300° C. and the reduced pressure is 50 Torr or less, for example. In the reduced pressure pressing process, Au on the second power electrode 41a of the second electrode plate 40 and the collector electrode 26 of the IGBT element 20 is diffused, and Ni and Sn are diffused and react (diffusional reaction). The second power electrode 41a will be joined to the collector electrode 26 of the IGBT element 20 (refer to FIG. 3).

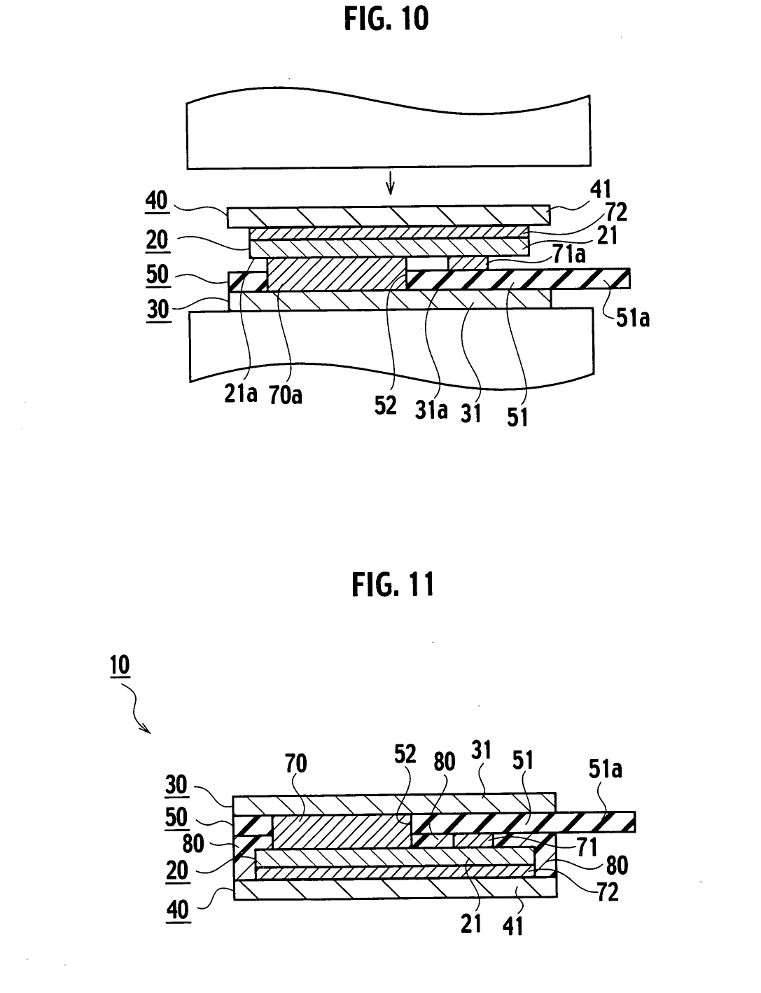

As shown in FIG. 10, the insulating substrate 50 is placed on the first electrode plate 30. A solder sheet 70a is fitted into a through-hole 52 of the insulating substrate 50. The solder sheet 70a is thicker than the insulating substrate 50. A solder sheet 71a in the pellet form which is as large as the gate electrode 23 (shown in FIG. 4) of the IGBT element 20 is placed on a bonding pad 54 (shown in FIG. 4) of the insulating substrate 50. Further, an additional solder sheet 71a is placed on the bonding pad 53 (shown in FIG. 4) of the insulating substrate 50. The solder sheets 71a are as large as the emitter-sense electrode 24 (shown in FIG. 4) of the IGBT element 20, and are placed on a bonding pad 54 (shown in FIG. 4) of the insulating substrate 50. The solder sheets 71a have thickness which is equal to a difference between thickness of the solder sheet 70a and thickness of the insulating substrate 50. The solder sheets 70a and 71a are made of Sn group solder materials. The first power electrode 30a of the first electrode plate 30, emitter electrode 22 on the surface 21a of the IGBT element 20, gate electrode 23 and emitter-sense electrode 24 are Ni/Au-plated in order to enhance solder wetting property.

Thereafter, the joined IGBT element 20 and second electrode plate 40 are placed on the insulating substrate 50 via the solder sheets 70a and 71a so that the IGBT element 20 faces with the insulating substrate 50. In this case, the solder sheet 70a is made to face with the emitter electrode 22 of the IGBT element 20 while the solder sheet 71a is made to face with the gate electrode 23 and the emitter-sense electrode 24 of the IGBT element 20 (refer to FIG. 4). The stacked IGBT element 20, first electrode plate 30, second electrode plate 40 and insulating substrate 50 are placed in the reduced pressure pressing machine, and are pressed under conditions similar to the foregoing conditions. In the reduced pressure pressing process, Au on the first power electrode 31a of the first electrode plate 30 and the electrodes of the IGBT element 20 is diffused, and Ni and Snare diffused and react (diffusional reaction). Thus, the first power electrode 31a of the first electrode plate 30 is joined to the emitter electrode 22 of the IGBT element 20, and the bonding pads 53 and 54 are joined to the emitter electrode 23 and the emitter-sense electrode 24 of the IGBT element 20 (refer to FIG. 4). The semiconductor package 10 as shown in FIG. 8 is completed.

In the semiconductor package 10 of the second embodiment, the electrodes are joined by the diffused junction in order to prevent solder fusion, which is effective in controlling the thickness of the solder layers 70, 71 and 72, in maintaining the parallelism of the first electrode plate 30 and the second electrode plate 40, and enabling the semiconductor package 10 to have constant thickness. Therefore, when a plurality of semiconductor packages 10 are assembled into a semiconductor module, the semiconductor module is free from problems related to the parallelism of the first electrode plates 30 and the second electrode plates 40, and thickness of the semiconductor packages 10.

### Third Embodiment

In a third embodiment, a semiconductor package 10 is essentially identical to the semiconductor package 10 of the second embodiment, but is different in the following respects.

Referring to FIG. 11, the semiconductor package 10 includes a resin part 80 which surrounds an IGBT element 20, and is provided between first and second electrode plates 30 and 40.

The resin part 80 is made by filling a resin into a space between the first and second electrode plates 30 and 40, and surrounds the IGBT element 20. The first and second electrode plates 30 and 40 are fixedly joined. The IGBT element 20 is surrounded by the resin part 80.

In the semiconductor package 10 of the third embodiment, the resin part 80 effective in making the semiconductor package 10 mechanically strong, and in preventing the IGBT element 20 from being broken due to external shocks and so on. Therefore, the reliability of the components of the semiconductor package 10 is improved.

### Fourth Embodiment

In a fourth embodiment, a semiconductor package 10 is essentially identical to the semiconductor package 10 of the first embodiment, but is different in the following respects.

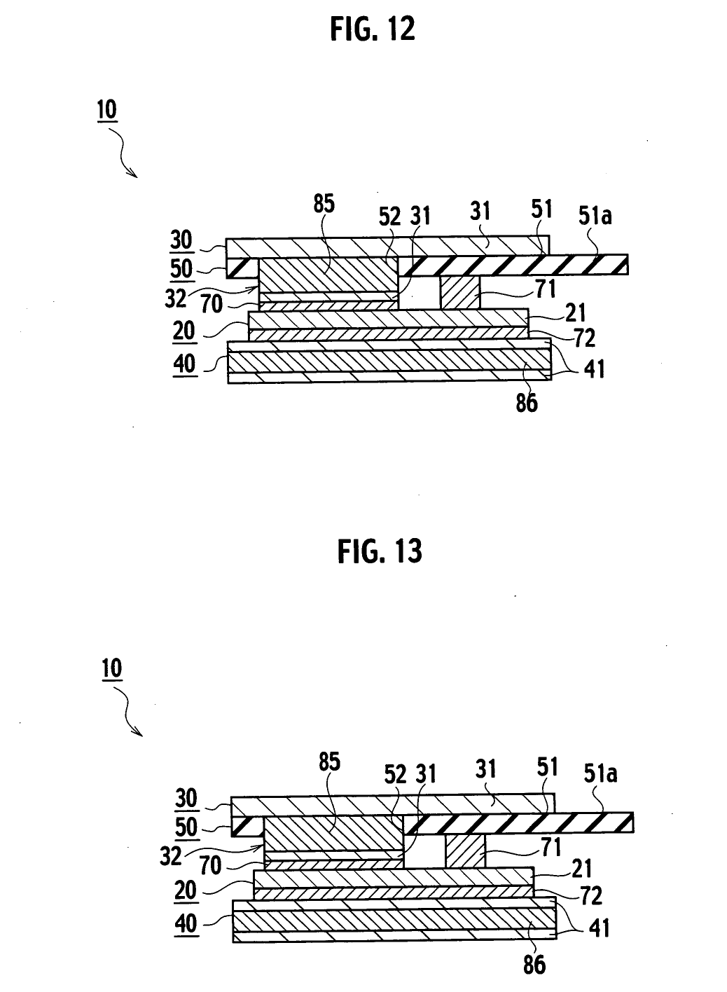

Referring to FIG. 12, the semiconductor package 10 includes a stress reducing layer 85 which is provided between an IGBT element 20 and a first electrode plate 30, and has stress reducing ability and conductivity. Further, a second electrode plate 40 is provided with a stress reducing layer 86 having the stress reducing ability and conductivity.

The stress reducing layer 85 projects on a substrate body 31 of the first electrode plate 30, serves as a first power electrode 32 (a protrusion), and is sandwiched as an intermediate layer by upper and lower parts 32a and 32b of the first power electrode 32. The upper part 32a of the first power electrode 32 is soldered to the substrate body 31, so that a solder layer 73 is formed between them. Further, the stress reducing layer 86 is served as an intermediate layer, and is provided as an intermediate layer in the substrate body 41 of the second electrode plate 40.

The stress reducing layers 85 and 86 are made of conductive materials such as copper wires woven in the shape of a net. However, they may be made of any materials and in any shape, and flexibly reduce stresses.

In the semiconductor package 10 of the fourth embodiment, the stress reducing layers 85 and 86 prevent the IGBT element 20 from being broken due to stresses. This improves the reliability of the components of the semiconductor package 10.

Further, during the manufacturing process (refer to FIG. 9 and FIG. 10), the IGBT element 20 of the semiconductor package 10 can be protected against damages caused by external stresses, which is effective in improving yield of the semiconductor package 10.

Still further, when a plurality of semiconductor packages 10 are assembled into a semiconductor module, they can be protected against breakage, especially, breakage of IGBT elements 20. This is effective in improving yield of the semiconductor module.

The stress reducing layers 85 and 86 are in the shape of a net, and can easily and flexibly reduce stresses.

### Fifth Embodiment

In a fifth embodiment, a semiconductor package 10 is essentially identical to the semiconductor package 10 of the first embodiment, but is different in the following respects.

Referring to FIG. 13, first and second electrode plates 30 and 40 include stress reducing layers 85 and 86, respectively. The stress reducing layers 85 and 86 have the stress reducing ability and conductivity.

The stress reducing layer 85 serves as an intermediate layer in a substrate body 31 of a first electrode plate 30, and serves as a first power electrode 32 (a protrusion). Further, the stress reducing layer 86 serves as an intermediate layer in a substrate body 41 of a second electrode plate 40.

The stress reducing layers 85 and 86 are made of conductive materials such as copper wires woven in the shape of a net. However, they may be made of any materials and in any shape, and flexibly reduce stresses.

In the semiconductor package 10 of the fifth embodiment, the stress reducing layers 85 and 86 prevent the IGBT element 20 from being broken due to stresses. This improves the reliability of the components of the semiconductor package 10.

Further, during the manufacturing process (refer to FIG. 9 and FIG. 10), the IGBT element 20 of the semiconductor package 10 can be protected against damages caused by external stresses, which is effective in improving yield of the semiconductor package 10.

When assembling a plurality of semiconductor packages 10 into a semiconductor module, the IGBT element 20 of the semiconductor package 10 can be protected against damages caused by external stresses, which is effective in improving yield of the semiconductor module.

### Sixth Embodiment

In a sixth embodiment, a semiconductor package 10 is essentially identical to the semiconductor package 10 of the first embodiment, but is different in the following respects.

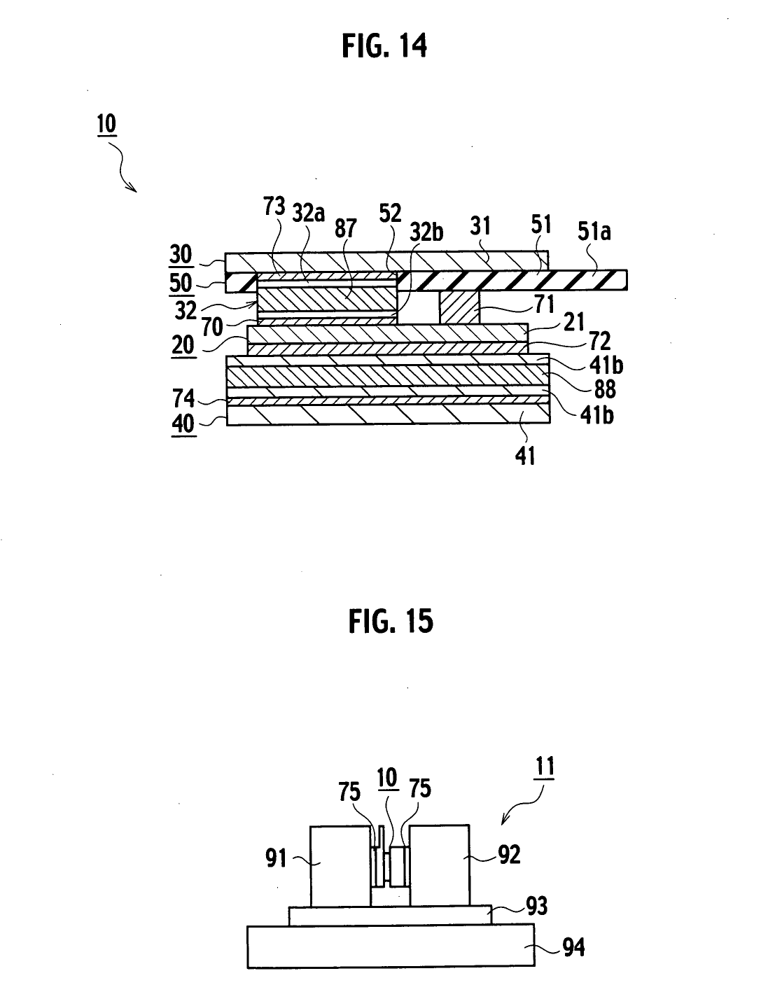

Referring to FIG. 14, the semiconductor package 10 includes a stress reducing layer 87 between an IGBT element 20 and a first electrode plate 30, and a stress reducing layer 88 between the IGBT element 20 and a second electrode plate 40. The stress reducing layers 87 and 88 have the stress reducing ability and conductivity.

The stress reducing layer 87 projects on the substrate body 31 of the first electrode plate 30 and serves as a first power electrode 32 (a protrusion), is sandwiched as an intermediate layer by upper and lower parts 32a and 32b of the first power electrode 32. The upper part 32a of the first power electrode 32 is soldered to the substrate body 31, so that a solder layer 73 is formed between them.

The stress reducing layer 88 functions as an intermediate layer in a stress reducing electrode 41b, and is soldered between the IGBT element 20 and the second electrode plate 40, so that a solder 72 is formed between the IGBT element 20 and the stress reducing electrode 41b, and a solder layer 74 is formed between the second electrode plate 40 and the stress reducing electrode 41b.

The stress reducing layers 87 and 88 are made of conductive materials such as thin copper wires woven in the shape of fabric straps. Alternatively, they may be made of any materials so long as they are flexible and can alleviate stress caused by thermal expansion of the IGBT element 20, and first and second electrode plates 30 and 40.

In the semiconductor package 10 of the sixth embodiment, the semiconductor package 10 includes the stress reducing layers 87 and 88, which protect the IGBT element 20 against stress. This is effective in improving the reliability of components of the semiconductor package 10.

Further, during the manufacturing process (refer to FIG. 9 and FIG. 10), the IGBT element 20 of the semiconductor package 10 can be protected against damages caused by external stresses, which is effective in improving yield of the semiconductor package 10.

Still further, when assembling a plurality of semiconductor packages 10 into a semiconductor module, the IGBT element 20 of the semiconductor package 10 can be protected against damages caused by external stresses, which is effective in improving yield of the semiconductor module.

### Seventh Embodiment

In a seventh embodiment, a semiconductor module 11 is constituted by a plurality of semiconductors 10 in any of the first to sixth embodiments. Refer to FIG. 15 and FIG. 16.

The semiconductor module 11 includes a plurality of semiconductor 10, a plurality of FRD elements 12 (high speed rectifying element), first and second conductive members 91 and 92 sandwiching the semiconductor packages 10 and the FRD elements 12, and a radiating plate 94 on which first and second conductive members 91 and 92 are provided via an insulator 93 such as an insulating sheet or an insulating plate.

The semiconductor packages 10 are soldered to the first and second conductive members 91 and 92, and are electrically connected, so that a solder layer 75 is formed between them. Further, the FRD elements 12 are soldered to the first and second conductive members 91 and 92, and are electrically connected, so that another solder layer 75 is between them. The diffused junction process is utilized for the foregoing process.

The conductive members 91 and 92 serve common electrodes for the semiconductor packages 10 and FRD elements 12, and further function as radiators because of thermal conductivity. Specifically, the first conductive member 91 is connected to the first electrode plates 30 (refer to FIG. 2) of the semiconductor packages 10, and also functions as an emitter electrode block. Further, the second conductive member 92 is connected to the second electrode plates 40 (refer to FIG. 2) of the semiconductor packages 10, and also functions as a collector electrode block.

In the semiconductor module 11 of the seventh embodiment, the semiconductor module 11 is as effective and advantageous as the semiconductor packages 10 of the first to sixth embodiments.

### Eighth Embodiment

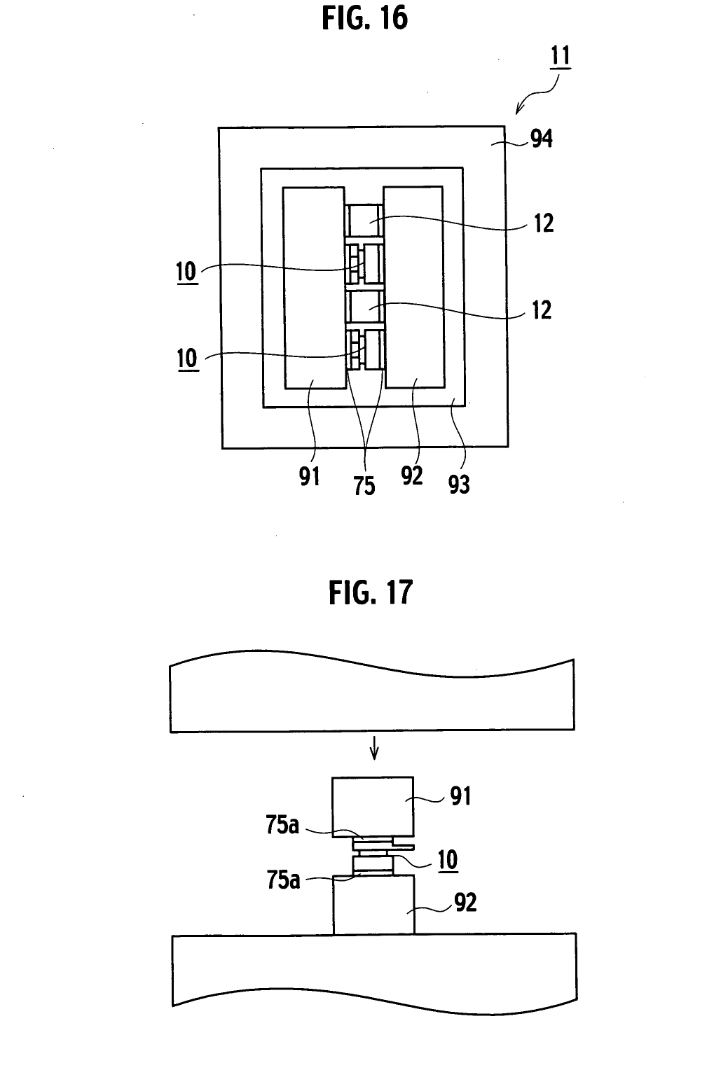

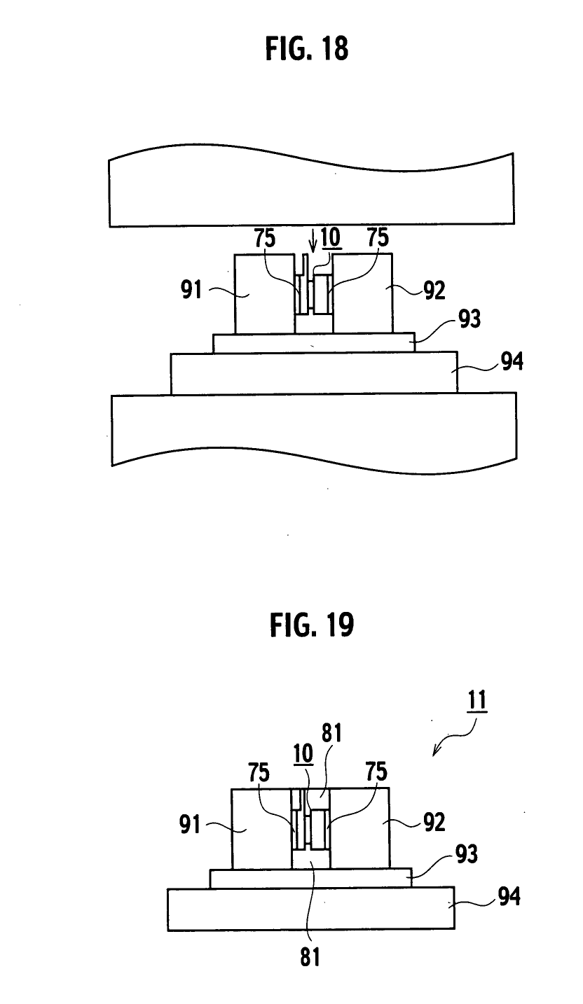

A semiconductor module 11 of an eighth embodiment is essentially identical to the semiconductor module 11 of the seventh embodiment, but is different in the following respects. Refer to FIG. 17 and FIG. 18.

The diffused junction is applied to form a solder layer 75 in the eighth embodiment. The semiconductor module 11 is assembled as described hereinafter.

Referring to FIG. 17, a plurality of semiconductor packages 10 and a plurality of FRD elements 12 are placed on a second conductive member 92 via a solder sheet 75a. Further, a first conductive member 91 is placed on the semiconductor packages 10 and FRD elements 12 via another solder sheet 75a. The foregoing components are placed in a reduced pressure pressing machine, and are pressed under predetermined conditions (e.g., a pressing pressure of 4 MPa, a temperature of 210° C., and pressure reduction of 10 Torr or less). The pressing conditions depend upon a composition and so on of the solder sheet 75a. By the way, in the sixth embodiment, the pressing pressure is 0.5 Mpa to 10 MPa, the temperature is 150° C. to 300° C., and the reduced pressure is 50 Torr or less, for example. The semiconductor packages 10 and the first and second conductive members 91 and 92 and FRD elements 12 are joined by the diffused junction using the reduced pressure pressing machine.

Thereafter, as shown in FIG. 18, the first and second conductive members 91 and 92 holding the semiconductor packages 10 and FRD elements 12 are placed on a radiator 94 via an insulator 93. In this state, the radiator 94 is placed in a hot press machine, and is hot-pressed under predetermined conditions. The first and second conductive members 91 and 92 are joined by the insulator 93 melted by the hot-press process. Thus, the semiconductor module 11 as shown in FIG. 15 and FIG. 16 is completed.

In the semiconductor module 11 of the eighth embodiment, The semiconductor module 11 is as effective and advantageous as the semiconductor packages 10 of the first to sixth embodiments. The diffused junction of the semiconductor packages 10 and the first and second conductive members 91 and 92 can prevent the semiconductor packages 10, especially the IGBT elements 20, from being damaged by coagulation or contraction of solders caused when they are joined by a molten solder. Therefore, it is possible to improve the yield of the semiconductor module 11.

### Ninth Embodiment

A ninth embodiment of the invention is essentially identical to the seventh or eighth embodiment, but is different in the following respects.

Referring to FIG. 19, a semiconductor module 11 of this embodiment includes a resin member 81 present between a first conductive member 91 and a second conductive member 92. Specifically, the resin member 81 surrounds the semiconductor module 11.

A resin as the resin member 81 is filled in a space between the first and second conductive members 91 and 92, and extends around semiconductor packages 10 and FRD elements 12 (show in FIG. 16). The resin member 81 is formed after the semiconductor packages 10 and the first and second conductive members 91 and 92 are joined(show in FIG. 17), and before the hot-soldering process (shown in FIG. 18).

In the semiconductor module 11 of the ninth embodiment, the semiconductor module 11 includes the resin member 81 between the first and second conductive members 91 and 92. The resin member 81 improves the mechanical strength of the semiconductor module 11, which is effective in protecting the semiconductor packages 10 from being broken due to external shocks. Further, the reliability of the components of the semiconductor module 11 is improved.

Further, a resin as the resin member 81 is filled between the first and second conductive members 91 and 92 before the semiconductor packages 10 and the conductive members 91 and 92 are placed on the radiator 94 and hot-pressed, so that the semiconductor packages 10, especially IGBT elements 20, are protected against damages caused by the hot-press process. Therefore, it is possible to improve the yield of the semiconductor module 11.

Although the present invention has been described and illustrated in detail, it is to be clearly understood that the same is by way of illustration and example only, and is not be taken by way of limitation. The invention may be modified in a variety of ways by combining or deleting a plurality of components referred to in the specification.

What is claimed is:

1. A semiconductor package comprising:
a plate-like semiconductor element having a first power terminal and a control terminal on a main surface, and a second power terminal on a rear surface;
a first power electrode plate positioned to face with the main surface of the semiconductor element, and including a first power electrode joined to the first power terminal by soldering;
a second power electrode plate positioned to face with the rear surface of the semiconductor element, and including a second power electrode joined to the second power terminal by soldering; and
an insulating substrate positioned between the semiconductor element and the first electrode plate, and including a control electrode joined to the control terminal by soldering.

2. The semiconductor package of claim 1, wherein the insulating substrate has a ledge sticking out from peripheral edges of the semiconductor element and the first and second electrode plates; and an external connection terminal connected to the control electrode is positioned on the ledge.

3. The semiconductor package of claim 1, wherein the first power electrode is in the shape of a projection sticking out toward the semiconductor element; and the insulating substrate has an opening or a cut through which the first power electrode passes.

4. The semiconductor package of claim 1, wherein the insulating electrode includes a fixing pad on a surface facing with the first electrode plate, and the first electrode plate and the fixing pad are joined by soldering.

5. The semiconductor package of claim 1, wherein peripheral edges of the second electrode plate and the insulating substrate are located outward of a peripheral edge of the semiconductor element; and a spacer is provided and maintains a predetermined space between the second electrode plate and the insulating substrate, and is located outward of the peripheral edge of the semiconductor element.

6. The semiconductor package of claim 5, wherein the spacer is covered with a metallic material, and is joined to the second electrode plate or the insulating substrate by soldering.

7. The semiconductor package of claim 5, wherein the spacer is a chip component having a built-in electric passive element.

8. The semiconductor package of claim 1, wherein the soldering is diffused junction of solder.

9. The semiconductor package of claim 1, further comprising a resin part surrounding the semiconductor element, and provided between the first and second electrode plates.

10. The semiconductor package of claim 1, further comprising a stress reducing layer having a stress reducing function and conductivity.

11. The semiconductor package of claim 1, wherein the first electrode plate includes a stress reducing layer having a stress reducing function and conductivity.

12. The semiconductor package of claim 1, wherein the second electrode plate includes a stress reducing layer having a stress reducing function and conductivity.

13. The semiconductor package of claim 10, wherein the stress reducing layer is in the shape of a net.

14. The semiconductor package of claim 11, wherein the stress reducing layer is in the shape of a net.

15. The semiconductor package of claim 12, wherein the stress reducing layer is in the shape of a net.

16. A semiconductor module constituted by a semiconductor package defined in claim 1, and the semiconductor packages being sandwiched by first and second conductive members.

17. The semiconductor module of claim 16, wherein the semiconductor package is joined to the first and second conductive members by diffused junction of solder.

18. The semiconductor module of claim 16, further comprising a resin member surrounding the semiconductor package, and provided between the first and second conductive members.
